(19) United States
(12) Patent Application Publication
(10) Pub. No.: US 2025/0051925 A1
(43) Pub. Date: Feb. 13, 2025

(54) METHDOS AND SYSTEMS FOR FILLING A GAP

(71) Applicant: ASM IP Holding B.V., Almere (NL)

(72) Inventors: Timothee Blanquart, Oud-Heverlee (BE); René Henricus Jozef Vervuurt, Leuven (BE)

(21) Appl. No.: 18/795,263

(22) Filed: Aug. 6, 2024

Related U.S. Application Data
(60) Provisional application No. 63/531,579, filed on Aug. 9, 2023.

(51) Int. Cl. C23C 16/56; C23C 16/455; C23C 16/52; H01L 21/3205

(52) U.S. Cl. CPC C23C 16/56; C23C 16/45544; C23C 16/52; H01L 21/32051

(57) ABSTRACT

Disclosed are methods and systems for filling a gap. An exemplary method comprises providing a substrate to a reaction chamber. The substrate comprises the gap. The method further comprises forming a convertible layer on the substrate and exposing the substrate to a conversion reactant. Accordingly, at least a part of the convertible layer is converted into a gap filling fluid. The gap filling fluid at least partially fills the gap. The methods and systems are useful, for example, in the field of integrated circuit manufacture.

### CROSS-REFERENCE TO RELATED APPLICATION

This application claims priority to and the benefit of U.S. Provisional Application No. 63/531,579, filed Aug. 9, 2023, the entirety of which is incorporated by reference herein.

### FIELD OF INVENTION

The present disclosure generally relates to the field of semiconductor processing methods and systems, and to the field of integrated circuit manufacture. In particular, methods and systems suitable for filling a gap are disclosed.

### BACKGROUND OF THE DISCLOSURE

The scaling of semiconductor devices, such as, for example, logic devices and memory devices, has led to significant improvements in speed and density of integrated circuits. However, conventional device scaling techniques face significant challenges for future technology nodes.

For example, one challenge has been finding suitable ways of filling gaps such as recesses, trenches, vias and the like with a material without formation of any gaps or voids.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of filling a gap, to structures and devices formed using such methods, and to apparatus for preforming the methods and/or for forming the structures and/or devices. The layers may be used in a variety of applications. For example, they may be used in the field of integrated circuit manufacture.

Thus, described herein is a method for filling a gap. The method comprises providing a substrate to a reaction chamber. The substrate comprises the gap. The method further comprises forming a convertible layer on the substrate. The method further comprises the substrate to a liquid phase conversion reactant. Thereby, at least a part of the convertible layer is converted into a gap filling fluid. Accordingly, the gap filling fluid as least partially fills the gap.

Further described herein is a system. The system comprises a reaction chamber. The system further comprises a precursor gas source. The precursor gas source comprises a metal precursor. The system further comprises a deposition reactant gas source. The deposition reactant gas source comprises a deposition reactant. The system further comprises a controller. The controller is configured to control gas flow into the reaction chamber to form a layer on a substrate by means and methods as described herein. These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates an embodiment of a method as disclosed herein.

FIG. 2 illustrates an embodiment of a method as disclosed herein.

FIG. 3 illustrates the operation of an embodiment of a method as described herein.

FIG. 4 shows another embodiment of a system (400) as described herein in a stylized way.

FIG. 5 shows a stylized representation of a substrate (500) comprising a gap (510).

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include at least one of bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

As used herein, a “structure” can be or can include a substrate as described herein. Structures can include one or more layers overlying the substrate, such as one or more layers formed according to a method as described herein. Device portions can be or include structures.

The term “deposition process” as used herein can refer to the introduction of precursors (and/or reactants) into a reaction chamber to deposit a layer over a substrate. “Cyclical deposition processes” are examples of “deposition processes”.

As used herein, the term “gap filling fluid”, also referred to as “flowable gap fill”, may refer to a composition of matter that is liquid, or that can form a liquid, under the conditions under which is formed and which has the capability to form a solid material in a gap. A “gap filling fluid” can, in some embodiments, be only temporarily in a flowable state, for example when the “gap filling fluid” is temporarily formed through formation of liquid oligomers from gaseous monomers during a polymerization reaction, and the liquid oligomers continue to polymerize to form a solid polymeric material; or when the gap filling fluid solidifies after cooling down; or when the gap filling fluid forms a solid material as it undergoes a chemical reaction. For ease of reference, a solid material formed from a gap filling fluid may, in some embodiments, be simply referred to as “gap filling fluid”.

A method as described herein can comprise depositing a layer by a cyclic deposition process. The term “cyclic deposition process” or “cyclical deposition process” can refer to a sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a CVD component.

A method as described herein can comprise depositing a layer by an atomic layer deposition process. The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forms about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example, in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element that may be incorporated during a deposition process as described herein.

The term “reactant” can refer to a gas or a material that can become gaseous and that can react with a precursor.

Further, in this disclosure, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X₁ and X₂) as well as a combination of elements selected from two or more classes (e.g., Y₁ and Zₒ).

In this disclosure, any defined meanings do not necessarily exclude ordinary and customary meanings, in some embodiments.

Described herein is a method of filling a gap. The method comprises providing a substrate that comprises a gap to a reaction chamber. A monocrystalline silicon wafer may be a suitable substrate. Other substrates may be suitable well, e.g. monocrystalline germanium wafers, gallium arsenide wafers, quartz, sapphire, glass, steel, aluminum, silicon-on-insulator substrates, plastics, etc.

The method further comprises forming a convertible layer on the substrate, and then exposing the substrate to a liquid phase conversion reactant. Accordingly, at least part of the convertible layer is converted into a gap filling fluid that at least partially fills the gap.

The presently disclosed method allows formation of a metal and halogen containing gap filling fluid.

In some embodiments, the metal and halogen containing gap filling fluid comprises oligomers that undergo chain growth as gaseous precursor polymerizes. Accordingly, a flowable oligomer-containing gap filling fluid can, in some embodiments, be temporarily formed on the substrate's surface that solidifies as the oligomers undergo chain growth. Thus, a flowable gap filling fluid can be obtained even at temperatures that are lower than the bulk melting point of a converted layer that is formed by a method as disclosed herein. Of course, the presently described methods can also be used at conversion temperatures which exceed the melting point of the converted layers formed by the presently described methods. In such cases, the gap filling fluid can, in some embodiments, be solidified by cooling the substrate down.

In some embodiments, the gap filling fluid is formed wherever a convertible layer is present on the substrate. When the substrate has a surface that is completely covered by the convertible layer, a gap filling fluid can be formed over the entire substrate surface, both outside gaps and inside gaps comprised in the substrate. When the substrate has a surface that is only partially covered by the convertible layer, then the gap filling fluid can be preferentially formed only in those places where the convertible layer is present. When the gap filling fluid is formed both outside of the gaps and inside the gaps, the gap filling fluid can, in some exemplary modes of operation, be drawn into a gap by at least one of capillary forces, surface tension, and gravity. It shall be understood that a distal portion of the gap feature refers to a portion of the gap feature that is relatively far removed from a substrate's surface, and that the proximal portion of a gap feature refers to a part of the gap feature that is closer to the substrate's surface compared to the lower/deeper portion of the gap feature.

The materials formed according to the present methods can be advantageously used in the field of integrated circuit manufacture.

Exemplary gaps include recesses, contact holes, vias, trenches, and the like. In some embodiments, the gap has a depth of at least 5 nm to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap has a width of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap has a length of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

The convertible layer can suitably be deposited using a deposition technique that yields conformal layers, such as atomic layer deposition (ALD) or another cyclical deposition process. Alternatively, the convertible layer can be deposited using a deposition technique that yields non-conformal layers, i.e. non-uniform layers, such as layers that have a higher thickness on a flat surface of a substrate, than inside a gap or trench; or layers that have a higher thickness inside a gap or trench than on a flat surface of a substrate. Examples of techniques that can yield non-conformal layers are chemical vapor deposition and plasma-enhanced chemical vapor deposition.

Depositing the convertible layer may comprise executing a cyclical deposition process. The cyclical deposition process can include cyclical CVD, ALD, or a hybrid cyclical CVD/ALD process. For example, in some embodiments, the growth rate of a particular ALD process may be low compared to a CVD process. One approach to increase the growth rate may be that of operating at a higher deposition temperature than that typically employed in an ALD process, resulting in some portion of a chemical vapor deposition process, i.e. of at least one of non-self-limiting surface and gas phase reactions, but still taking advantage of the sequential introduction of reactants. Such a process may be referred to as cyclical CVD. In some embodiments, a cyclical CVD process may comprise the introduction of two or more precursors or reactants into the reaction chamber, wherein there may be a time period of overlap between the two or more precursors or reactants in the reaction chamber resulting in both an ALD component of the deposition and a CVD component of the deposition. This is referred to as a hybrid process. In accordance with further examples, a cyclical deposition process may comprise a continuous flow of one reactant or precursor and periodic pulsing of a second reactant or precursor into the reaction chamber.

In some embodiments, the convertible layer is conformally deposited on the substrate. In other words, the convertible layer can have a thickness which is constant over the surface of the substrate, including in gaps, recesses, and the like, e.g. within a margin of error of 50%, 20%, 10%, 5%, 2%, 1%, 0.5%, or 0.1%.

In some embodiments, the convertible layer is deposited by a deposition method that yields a growth rate at a distal surface of a gap that is higher than a growth rate at a proximal surface of the gap. In some embodiments, the growth rate at the distal surface of the gap is from at least 200% to at most 500%, or from at least 100% to at most 200%, or from at least 50% to at most 100%, or from at least 20% to at most 50%, or from at least 10% to at most 20%, or from at least 5% to at most 10%, or from at least 2% to at most 5%, or from at least 1% to at most 2% higher than the growth rate at the proximal surface of the gap.

Suitable convertible layers include layers that comprise at least one of a metal, a metal oxide, a metal nitride, and a metal carbide. For example, the convertible layer can comprise an element selected from the group consisting of tungsten (W), germanium (Ge), antimony (Sb), tellurium (Te), niobium (Nb), tantalum (Ta), vanadium (V), titanium (Ti), zirconium (Zr), rhodium (Rh), iron (Fe), chromium (Cr), molybdenum (Mo), gold (Au), platinum (Pt), silver (Ag), nickel (Ni), copper (Cu), cobalt (Co), zinc (Zn), aluminum (Al), indium (In), tin (Sn), hafnium (Hf), ruthenium (Ru), and bismuth (Bi).

In some embodiments, the convertible layer is at least partially metallic. In some embodiments, the convertible layer comprises a metal alloy. Thus, and in some embodiments, the convertible layer comprises an elemental metal, e.g. an elemental metal having an impurity content of less than 10 atomic percent, of less than 5 atomic percent, of less than 2 atomic percent, or of less than 1 atomic percent.

Additionally or alternatively, the convertible layer can be at least partially semiconducting.

Additionally or alternatively, the convertible layer can be at least partially dielectric.

In some embodiments, the convertible layer comprises a metal oxide.

In some embodiments, the convertible layer comprises a metal nitride.

In some embodiments, the convertible layer comprises a metal atom which is capable of forming a volatile halide or oxyhalide compound. Examples of these volatile halide and oxyhalide compounds are RhBr₃, FeBr₃, FeBr₂, CrF₅, Co₆Cl₁₂, MoCl₄, MoI₃, MoBr₃, AlCl₃, AlI₃, InBr₃, SnCl₂, SnBr₂, BiF₅, GeF₂, GeF₄, SbF₃, SbF₅, Te₂Br, AuF₃, AuBr, PtBr₄, AgF₃, NiBr₂, CuBr₂, CoI, ZnCl₂, ZnI₂, NbCl₄, NbI₅, TaCl₅, TaI₅, TaF₅, TaBr₅, VF₄, VF₅, VBr₃, TiF₄, ZrI₄, ZrCl₄, ZrBr₄, HfCl₄, HfI₄, WOBr, WOCl₄, NbOCl₃, V₂O₂F₄, VOCl₂, VOCl₃, VOF₃, ZrF₆ (H₂O)₂, or CoCl₂ (H₂O)₂.

In accordance with some examples of the disclosure, forming the convertible layer comprises a thermal deposition process. In these cases, the deposition process does not include generating a plasma to form activated species for use in the deposition process.

In some embodiments, the liquid phase conversion reactant comprises a halogen. Suitable halogen-containing conversion reactants include elemental halogens and hydrogen halides. For example, the conversion reactant can comprise an elemental halogen selected from F₂, Cl₂, Br₂, or I₂. Additionally or alternatively, the conversion reactant can comprise a hydrogen halide selected from HF, HCl, HBr, or HI. In some embodiments, the halogen-containing conversion reactant is an aqueous solution.

In some embodiments, the liquid phase conversion reactant comprises a compound that has a structure according to the general formula (i)

HXOₙ (i)

wherein X is halogen selected from the group consisting of F, Cl, Br and I, and wherein n is an integer with a value of 1, 2, 3 or 4.

In some embodiments, the liquid phase conversion reactant is selected from the group consisting of semi-metal halides, sulfonic acids, sulfonates, antimony salts, halo-halogens, nitro-halides, oxyhalides, heteroleptic-boron halides, sulfenyl halides, selenenyl halides, substituted pentafluoro sulfanyls, substituted sulfur trifluoride, organo-sulfuryl halides, and halo-succinimides. In some embodiments, the liquid phase conversion reactant is selected from the group consisting of 2,2-difluoro-1,3-dimethylimidazolidine (DFI), perfluorodecanoic acid (PFDA), fluorosulfuric acid (HSO₃F), antimony pentachloride (SbCl₅), diethylaminosulfur trifluoride (DAST), peroxydicarbonic difluoride (C₂F₂O₄), and bromine trifluoride (BrF₃). In some embodiments, the liquid phase conversion reactant is selected from the group consisting of α-fluoroalkylamines. In some embodiments, the α-fluoroamine comprises a compound containing at least one carbon atom that is bonded to both a nitrogen atom and a fluorine atom. In some embodiments, the α-fluoroamine has a formula of R₂NCF₂R′, where the R groups are independently any C1 to C6 hydrocarbon, and the R′ group is any one of the following: a C1-C6 hydrocarbon, a partially fluorinated C1-C6 hydrocarbon, a perfluoroalkyl group, a perfluoroaryl group, or an —NR₂ group. In some embodiments, the R or R′ groups are cyclic. In some embodiments, the cyclic R or R′ groups incorporate the “NCF₂” fragment of the α-fluoroamine. In some embodiments, the α-fluoroamine is 1,1,2,2,-tetrafluoroethyl-N,N-dimethylamine. In some embodiments, the α-fluoroamine is, 2,2-difluoro-1,3-dimethylimidazolidine. In some embodiments, the α-fluoroamine is N,N-diethyl-1,1,2,3,3,3-hexafluoro-1-propanamine. In some embodiments, the α-fluoroamine is 2-chloro-N,N-diethyl-1,1,2-trifluoroethanamine.

In some embodiments, the liquid phase conversion reactant is selected from the group consisting of sulfur chlorides, phosphorous chlorides, acyl chlorides, n-chlorosuccimide and t-butyl hypochlorite. In some embodiments, the liquid phase conversion reactant is selected from the group consisting of oxalyl chloride, acetyl chloride, thionyl chloride, sulfuryl chloride, alkyl sulfonyl chloride, disulfur dichloride and sulfur dichloride. In some embodiments, the liquid phase conversion reactant is selected from the group consisting of phosphorous trichloride, phosphorous pentachloride, phosphorous oxychloride, dialkylphosphinic chloride, diarlphosphinic chloride, alkylphosphonic dichloride, arylphosphonic dichloride, n-chlorosuccimide, alkyl hypochlorite and tert-butyl hypochlorite.

In some embodiments the liquid phase conversion reactant is selected from the group consisting of 1,1-dibromoalkanes, 1,2-dibromoalkanes, 1,1-diiodoalkanes, 1,2-diiodoalkanes, bromobenzene, iodobenzene, chlorobromide, chloroiodide, bromoiodide, oxalyl bromide, oxalyl iodide, silicon tetrabromide, silicon tetraiodide, dibromosilane, diiodosilane, tionyl bromide, tionyl iodide, tin bromide, tin iodide, aluminum bromide, aluminum iodide, titanium bromide, titanium iodide, phosphorous tribromide, phosphorous pentabromide, phosphorous oxybromide, phosphorous oxyiodide, N-bromosuccimide, N-iodosuccimide, tert-butyl hypobromite, ammonium bromide, ammonium iodide, pyrium bromide and pyridinum iodide.

In some embodiments, the liquid phase conversion reactant is selected from the group consisting of a vicinal diiodoalkane of the formula RR′XCCR″R′″X where X is iodine and where R and R′ and R″ and R′″ are independently any C1 to C10 alkyl group, including branched or cyclic variants, or is an aryl group comprising 6-10 carbon atoms.

In some embodiments, the liquid phase conversion reactant is selected from the group consisting of n-iodosuccinimide, 1,3-diiodo-5,5-dimethylhydantoin, N-iodosaccharin, diiodosilane, iodotrimethylsilane, tetramethylammonium iodide, tetrabutylammonium iodide, pyridinium iodide, pyrazinium iodide, pyrrolidinium iodide, acetyl iodide, 2,2-Dimethylpropanoyl iodide, benzoyl iodide, boron triiodide, diphosphorus tetraiodide and phosphorous triiodide.

In some embodiments, the substrate is maintained at a temperature of at least −25° C. to at most 400° C., or at a temperature of at least 0° C. to at most 200° C., or at a temperature of at least 25° C. to at most 150° C., or at a temperature of at least 50° C. to at most 100° C. while exposing the substrate to the active species.

In some embodiments, the convertible layer is deposited at a substrate temperature of less than 800° C., or of at least 50° C. to at most 500° C., or of at least 100° C. to at most 300° C. In some embodiments, the convertible layer is deposited at a temperature of at least −25° C. to at most 300° C., or at a temperature of at least 0° C. to at most 250° C., or at a temperature of at least 25° C. to at most 200° C., or at a temperature of at least 50° C. to at most 150° C., or at a temperature of at least 75° C. to at most 125° C.

In some embodiments, and while the substrate is exposed to a conversion reactant, the substrate is maintained at a temperature of less than 800° C., or of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C.

In some embodiments, and while the gap filling fluid is transformed into a transformed material, the substrate is maintained at a temperature of less than 800° C., or of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C. In some embodiments, the temperature at which the substrate is maintained while the substrate is exposed to a conversion reactant equals the temperature at which the substrate is maintained while the gap filling fluid is transformed into a transformed material.

In some embodiments, the presently described methods are carried out at a pressure of less than 760 Torr or of at least 0.2 Torr to at most 760 Torr, of at least 1 Torr to at most 100 Torr, or of at least 1 Torr to at most 10 Torr. In some embodiments, the convertible layer is deposited at a pressure of at most 10.0 Torr, or at a pressure of at most 5.0 Torr, or at a pressure of at most 3.0 Torr, or at a pressure of at most 2.0 Torr, or at a pressure of at most 1.0 Torr, or at a pressure of at most 0.1 Torr, or at a pressure of at most 10-2 Torr, or at a pressure of at most 10-3 Torr, or at a pressure of at most 10-4 Torr, or at a pressure of at most 10-5 Torr, or at a pressure of at least 0.1 Torr to at most 10 Torr, or at a pressure of at least 0.2 Torr to at most 5 Torr, or at a pressure of at least 0.5 Torr to at most 2.0 Torr.

In some embodiments, the substrate is exposed to the conversion reactant for a duration of at least 0.1 s to at most 1000 s, or of at least 0.2 s to at most 500 s, or of at least 0.5 s to at most 200 s, or of at least 1.0 s to at most 100 s, or of at least 2 s to at most 50 s, or of at least 5 s to at most 20 s.

In some embodiments, the method further comprises a step of curing the gap filling fluid. In some embodiments, curing can be performed after all of the gap filling fluid has been deposited. Alternatively, curing can be done cyclically. For example, a method as described herein can comprise a curing step after each step of exposing the substrate to a conversion reactant. Alternatively, a method as described herein can comprise a curing step after every other step of exposing the substrate to a conversion reactant. Alternatively, a method as described herein can comprise a curing step after from at least 1% to at most 2%, or from at least 2% to at most 5%, or from at least 5% to at most 10%, or from at least 10% to at most 20%, or from at least 20% to at most 50%, or from at least 50% to at most 100% of the steps of exposing the substrate to a conversion reactant.

A curing step suitably comprises subjecting the substrate to a form of energy, e.g. at least one of heat energy, radiation, and particles. Exemplary curing steps comprise exposing the substrate to UV radiation. Additionally or alternatively, a curing step can comprise exposing the substrate to a direct plasma, e.g. a noble gas plasma such as an argon plasma. Additionally or alternatively, a curing step can comprise exposing the substrate to one or more reactive species such as ions and/or radicals generated in a remote plasma, e.g. a remote noble gas plasma, such as a remote argon plasma. Additionally or alternatively, a curing step can comprise exposing the substrate to photons, e.g. at least one of UV photons, photons in the visible spectrum, IR photons, and photons in the microwave spectrum. Additionally or alternatively, a curing step can comprise heating the substrate.

In some embodiments, the convertible layer can comprise niobium (Nb), for example metallic niobium or a niobium oxide or nitride. In such embodiments, the conversion reactant can suitably comprise one of chlorine or iodine. Accordingly, a gap filling fluid comprising at least one of NbCl₄ or NbI₅ can be formed.

In some embodiments, the convertible layer can comprise tantalum (Ta), for example metallic tantalum or a tantalum oxide or nitride. In such embodiments, the conversion reactant can suitably comprise one of fluorine, chlorine, bromine, and iodine. Accordingly, a gap filling fluid comprising at least one of TaCl₅, TaI₅, TaF₅, or TaBr₅ can be formed.

In some embodiments, the convertible layer can comprise vanadium (V), for example metallic vanadium or a vanadium oxide or nitride. In such embodiments, the conversion reactant can suitably comprise one of fluorine and bromine. Accordingly, a gap filling fluid comprising at least one of VOCl₃, VF₄, VF₅, or VBr₃ can be formed.

In some embodiments, the convertible layer can comprise titanium (Ti), for example metallic titanium or a titanium oxide or nitride. In such embodiments, the conversion reactant can suitably comprise fluorine. Accordingly, a gap filling fluid comprising TiF₄ can be formed.

In some embodiments, the convertible layer can comprise zirconium (Zr), for example metallic zirconium or a zirconium oxide or nitride. In such embodiments, the conversion reactant can suitably comprise one of chlorine, bromine, and iodine. Accordingly, a gap filling fluid comprising at least one of ZrI₄, ZrCl₄, or ZrBr₄ can be formed.

In some embodiments, the convertible layer can comprise hafnium (Hf), for example metallic hafnium or a hafnium oxide or nitride. In such embodiments, the conversion reactant can suitably comprise one of chlorine and iodine. Accordingly, a gap filling fluid comprising at least one of HfCl₄ or HfI₄ can be formed.

In some embodiments, the convertible layer can comprise rhodium (Rh), for example metallic rhodium or rhodium oxide or nitride. In such embodiments, the conversion reactant can suitably comprise bromine. Accordingly, a gap filling fluid comprising RhBr₃ can be formed.

In some embodiments, the convertible layer can comprise iron (Fe), for example metallic iron or iron oxide or nitride. In such embodiments, the conversion reactant can suitably comprise bromine. Accordingly, a gap filling fluid comprising at least one of FeBr₃ or FeBr₂ can be formed.

In some embodiments, the convertible layer can comprise chromium (Cr), for example metallic chromium or chromium oxide or nitride. In such embodiments, the conversion reactant can suitably comprise fluorine. Accordingly, a gap filling fluid comprising CrF₅ can be formed.

In some embodiments, the convertible layer can comprise molybdenum (Mo), for example molybdenum or molybdenum oxide or nitride. In such embodiments, the conversion reactant can suitably comprise chlorine, bromine, or iodine. Accordingly, a gap filling fluid comprising at least one of Mo₆Cl₁₂, MoCl₄, MoI₃, or MoBr₃ can be formed.

In some embodiments, the convertible layer comprises gold (Au), for example metallic gold or an inorganic gold compound. In such embodiments, the conversion reactant can suitably comprise fluorine or bromine. Accordingly, a gap filling fluid comprising at least one of AuF₃ or AuBr can be formed.

In some embodiments, the convertible layer comprises silver (Ag), for example, metallic silver or an inorganic silver compound. In such embodiments, the conversion reactant can suitably comprise fluorine. Accordingly, a gap filling fluid comprising AgF₃ can be formed.

In some embodiments, the convertible layer comprises platinum (Pt), for example metallic platinum or an inorganic platinum compound. In such embodiments, the conversion reactant can suitably comprise bromine. Accordingly, a gap filling fluid comprising PtBr₄ can be formed.

In some embodiments, the convertible layer comprises nickel (Ni), for example metallic nickel or an inorganic nickel compound. In such embodiments, the conversion reactant can suitably comprise bromine. Accordingly, a gap filling fluid comprising NiBr₂ can be formed.

In some embodiments, the convertible layer comprises copper (Cu), for example metallic copper or an inorganic copper compound. In such embodiments, the conversion reactant can suitably comprise bromine. Accordingly, a gap filling fluid comprising CuBr₂ can be formed.

In some embodiments, the convertible layer comprises cobalt (Co), for example metallic cobalt or an inorganic cobalt compound. In such embodiments, the conversion reactant can suitably comprise iodine. Accordingly, a gap filling fluid comprising Col can be formed.

In some embodiments, the convertible layer comprises zinc (Zn), for example, metallic Zn or an inorganic Zn compound. In such embodiments, the conversion reactant can suitably comprise at least one of chlorine and iodine. Accordingly, a gap filling fluid comprising at least one of ZnCl₂ or ZnI₂ can be formed.

In some embodiments, the convertible layer can comprise aluminum (Al), for example metallic aluminum or an inorganic aluminum compound such as aluminum oxide or nitride. In such embodiments, the conversion reactant can suitably comprise chlorine or iodine. Accordingly, a gap filling fluid comprising at least one of AlCl₃ or AlI₃ can be formed.

In some embodiments, the convertible layer can comprise indium (In), for example metallic indium or an inorganic indium compound such as indium oxide or nitride. In such embodiments, the conversion reactant can suitably comprise bromine. Accordingly, a gap filling fluid comprising InBr₃ can be formed.

In some embodiments, the convertible layer can comprise tin (Sn), for example metallic tin or an inorganic tin compound such as tin oxide or nitride. In such embodiments, the conversion reactant can suitably comprise at least one of chlorine and bromine. Accordingly, a gap filling fluid comprising at least one of SnCl₂ or SnBr₂ can be formed.

In some embodiments, the convertible layer can comprise bismuth (Bi), for example metallic bismuth or an inorganic bismuth compound such as bismuth oxide or nitride. In such embodiments, the conversion reactant can suitably comprise fluorine. Accordingly, a gap filling fluid comprising BiF₅ can be formed.

In some cases, it can be desirable to alter a material that is formed by a method as described herein into a different form. Thus, in some embodiments, a method as described herein further comprises a transformation treatment. A suitable transformation treatment includes one or more of a thermal anneal, exposing the substrate to a reactant, exposing the substrate to a direct plasma, or exposing the substrate to active species such as ions or radicals that are generated in a remote plasma.

In other words, a gap filling fluid, in a liquid or solid state, can be subjected to a transformation treatment to form a solid transformed material. Suitable transformation treatments include exposure to a direct or remote plasma, and exposure to a thermal transformation. Suitable plasmas include remote and direct hydrogen plasmas, oxygen plasmas, or nitrogen plasmas. Suitable thermal transformation reagents include gasses and vapors containing at least one of hydrogen, oxygen, or nitrogen. Thus, a gap can be suitably filled with a transformed material of choice. The transformed material can comprise, for example, at least one of a metal, a nitride, or an oxide.

In some embodiments, the transformation treatment includes exposing the substrate to a direct plasma, such as a direct nitrogen plasma or a direct oxygen plasma. Suitable nitrogen plasmas employ a plasma gas comprising a nitrogen containing gas or vapor, such as N₂ and/or NH₃. Suitable oxygen plasmas employ a plasma gas comprising an oxygen containing gas or vapor, such as O₂ and/or H₂O.

In some embodiments, the transformation treatment includes a thermal process, such as a thermal process that comprises exposing the substrate to an oxygen reactant.

In some embodiments, transforming the gap filling fluid comprises exposing the substrate to a reduction step and to an oxidation step. In some embodiments, the reduction step precedes the oxidation step. Alternatively, the oxidation step can precede the reduction step. In some embodiments, the reduction step comprises exposing the substrate to a hydrogen plasma. In some embodiments, the oxidation step comprises exposing the substrate to an oxygen plasma.

In some embodiments, transforming the gap filling fluid comprises exposing the gap filling fluid or the converted material to a reduction step and to a nitridation step. It shall be understood that a nitridation step refers to a step of converting a material into a nitride. In some embodiments, the reduction step precedes the nitridation step. Alternatively, the nitridation step can precede the reduction step. In some embodiments, the reduction step comprises exposing the substrate to a hydrogen plasma. In some embodiments, the nitridation step comprises exposing the substrate to a nitrogen plasma. Suitable nitrogen plasmas include plasmas in which the plasma gas comprises at least one of N₂, NH₃, or mixtures comprising N₂ and H₂.

The transformation treatment can, in some embodiments, be carried out once after the gap has been filled, or it can be carried out multiple times, i.e. gap filling steps and transformation steps can be carried out alternatingly and cyclically in order to fill a gap with a transformed material. Thus, in some embodiments, a method as described herein can comprise executing a plurality of super cycles. A super cycle comprises, in the following order: forming the convertible layer on the substrate; exposing the substrate to the conversion reactant; and, subjecting the substrate to the transformation treatment. In some cases, carrying out a cyclical transformation treatment can result in a transformed layer having advantageous properties, such as higher etch resistance and/or less stress.

Thus, in some embodiments, a method as described herein comprises a plurality of super cycles. For example, a method as described herein can comprise from at least 2 to at most 5, or from at least 5 to at most 10, or from at least 10 to at most 20, or from at least 20 to at most 50, or from at least 50 to at most 100 super cycles. A super cycle comprises forming a convertible layer on the substrate; exposing the substrate to a conversion reactant; and optionally transforming the gap filling fluid into a transformed material.

The total number of super cycles comprised in a method as described herein depends, inter alia, on the total layer thickness that is desired. In some embodiments, the method comprises from at least 1 super cycle to at most 100 super cycles, or from at least 2 super cycles to at most 80 super cycles, or from at least 3 super cycles to at most 70 super cycles, or from at least 4 super cycles to at most 60 super cycles, or from at least 5 super cycles to at most 50 super cycles, or from at least 10 super cycles to at most 40 super cycles, or from at least 20 super cycles to at most 30 super cycles. In some embodiments, the method comprises at most 100 super cycles, or at most 90 super cycles, or at most 80 super cycles, or at most 70 super cycles, or at most 60 super cycles, or at most 50 super cycles, or at most 40 super cycles, or at most 30 super cycles, or at most 20 super cycles, or at most 10 super cycles, or at most 5 super cycles, or at most 4 super cycles, or at most 3 super cycles, or at most 2 super cycles, or a single super cycle.

Further described herein is a system that comprises a reaction chamber, a precursor gas source, a deposition reactant gas source, and a controller. The precursor gas source comprises a metal precursor, the deposition reactant gas source comprises a deposition reactant. The controller is configured to control gas flow into the reaction chamber to form a layer on a substrate by a method as described herein.

Optionally, the system further comprises one or more of an active species source and a transformation reactant source. The active species source is, if present, arranged for providing an active species. The transformation reactant source is, if present, arranged for providing a conversion reactant.

In some embodiments, the system comprises two distinct, i.e. separate, reaction chambers: a first reaction chamber and a second reaction chamber. The first reaction chamber is configured for forming a convertible layer on a substrate. The second reaction chamber is configured for exposing the substrate to an active species, for converting a gap filling fluid or a solidified material into a converted material, or both.

In some embodiments, the first reaction chamber and second reaction chamber form part of a cluster tool and a substrate moves between the first reaction chamber and second reaction chamber without an air break. In some embodiments, the first reaction chamber is maintained at a first reaction chamber temperature, and the second reaction chamber is maintained at a second reaction chamber temperature. In some embodiments, the first reaction chamber temperature is lower than the second reaction chamber temperature, for example, from at least 10° C. lower to at most 100° C. lower. In some embodiments, the first reaction chamber temperature is higher than the second reaction chamber temperature, for example from at least 10° C. higher to at most 100° C. higher. In some embodiments, the first reaction chamber temperature is equal to the second reaction chamber temperature, e.g. within a margin of 10° C., 20° C., 30° C., or 40° C.

In some embodiments, the second reaction chamber is configured to expose the material to the halogen reactant by at least one of the following methods: dip coating, spin coating, sol-gel, or chemical bath.

In accordance with yet additional embodiments of the disclosure, a device or portion thereof can be formed using a method and/or a structure as described herein. The device can include a substrate, one or more insulating layers, one or more metallic layers, and one or more semiconducting layers. The device further comprises a gap filled according to a method as disclosed herein.

Further described is a field effect transistor comprising a gate contact comprising a layer formed according to a method as described herein.

Further described is a metal contact comprising a layer deposited by a method as described herein.

Further provided herein is a metal-insulator-metal (MIM) capacitor comprising a metal electrode comprising a layer formed by a method as described herein.

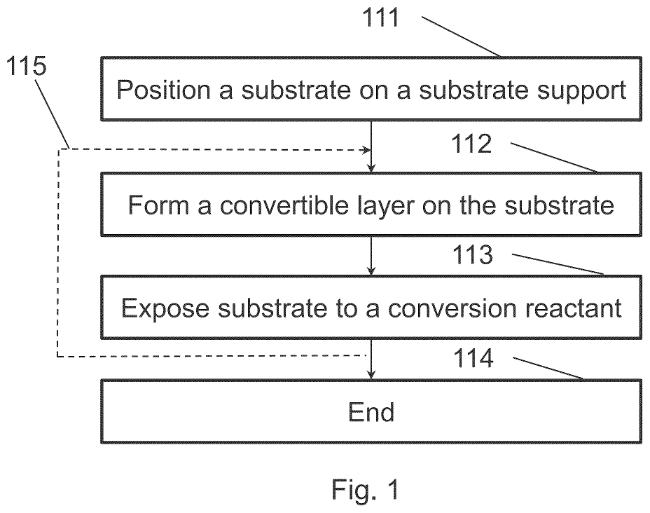

FIG. 1 shows a schematic representation of an embodiment of a method as described herein. The method can be used to fill a gap, for example, in order to form an electrode in a semiconductor device. However, unless otherwise noted, the presently described methods are not limited to such applications. The method comprises a step (111) of positioning a substrate on a substrate support. The substrate support is positioned in a reaction chamber. Suitable substrate supports include pedestals, susceptors, or the like.

The method further comprises forming a convertible layer on the substrate (112). Optionally, the reaction chamber is then purged. Then, the method comprises exposing the substrate to a liquid phase conversion reactant (113). In some embodiments, the exposure (113) is done by at least one of the following methods selected from the group consisting of: dip coating, spin coating, sol-gel and chemical bath. In some embodiments, the conversion reactant is heated before and/or during the exposure (113). In some embodiments, the conversion reactant is heated to a temperature between 20 and 200° C. In some embodiments, the exposure step (113) is performed in a sonic bath.

Accordingly, a gap filling fluid is formed in the gap. Optionally, the step of forming a convertible layer on the substrate (112) and the step of exposing the substrate to a liquid phase conversion reactant (113) are repeated (115) one or more times. When a sufficient amount of gap filling fluid has been formed in the gap, the method ends (114).

Optionally, a purge is carried out after forming a convertible layer on the substrate (112) by a post-deposition purge. Purging can be done by exposing the substrate to a purge gas that, in turn, can be done, for example, by providing a purge gas to the reaction chamber. Exemplary purge gasses include noble gasses. Exemplary noble gasses include He, Ne, Ar, Xe, or Kr. Alternatively, the purging can comprise transporting the substrate through a purge gas curtain. During a purge, surplus chemicals and reaction byproducts, if any, can be removed from the substrate surface or reaction chamber, such as by purging the reaction space or by moving the substrate, before the substrate is subjected to a next step.

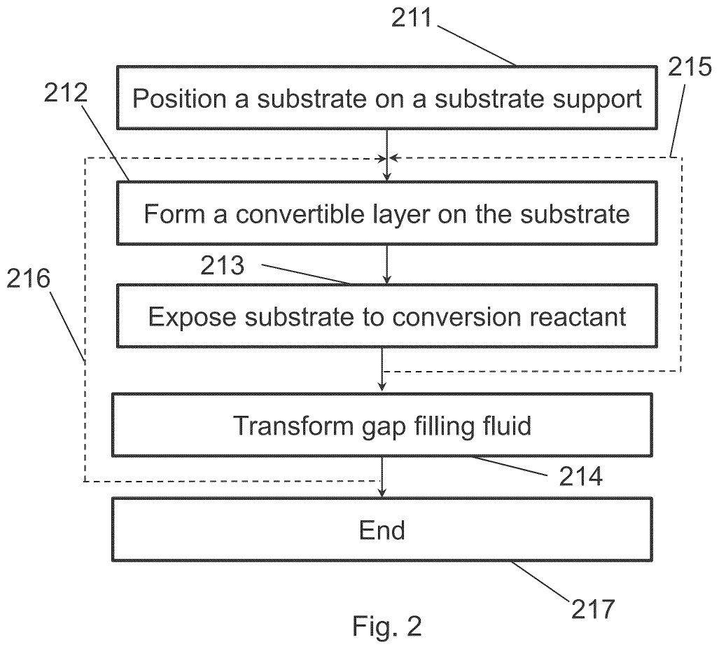

FIG. 2 schematically shows another embodiment of a method as described herein. The method of FIG. 2 is similar to that of FIG. 1 in the sense that it also comprises positioning a substrate on a substrate support (211), forming a convertible layer on the substrate (212), and exposing the substrate to a liquid phase conversion reactant (213). As before, the steps of forming a convertible layer on the substrate (212) and converting the convertible layer to form a gap filling fluid (213) can be repeated (215) one or more times.

The method of FIG. 2 differs from the method of FIG. 1 in that it further comprises a step of transforming the gap filling fluid (214) to form a transformed material. Optionally, a purge is carried out after the step of transforming the gap filling fluid (214). The step of transforming the gap filling fluid (214) can comprise, for example, exposing the substrate to a direct plasma such as a direct oxygen plasma or a direct nitrogen plasma. Optionally, the method of FIG. 2 comprises a plurality of super cycles (216) in which the steps from forming a convertible layer on the substrate (212) to transforming the gap filling fluid (214) are repeated one or more times. After a pre-determined amount of converted material has been formed on the substrate, the method of FIG. 2 ends (217).

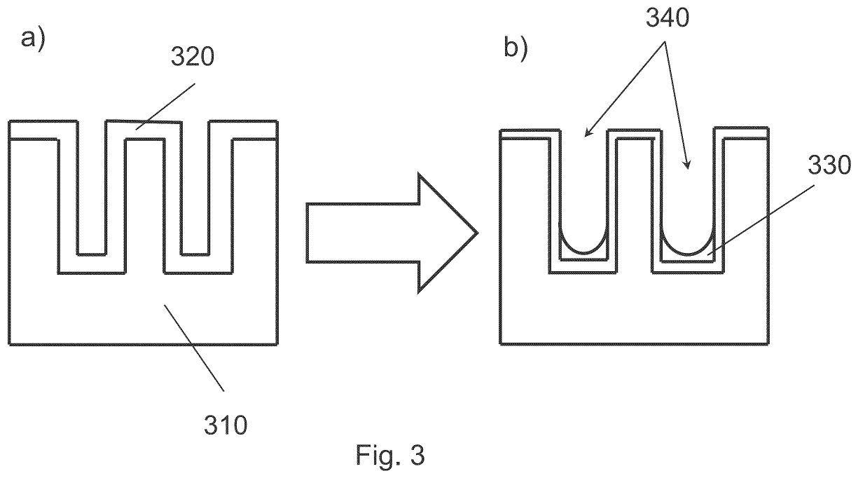

FIG. 3 illustrates the operation of a method as described herein. In particular, FIG. 3 shows a substrate (310) comprising a plurality of gaps (340). Panel a) shows a convertible layer (320) that is conformally deposited on the substrate (310). Panel b) shows the same substrate (310) after it has been exposed to a conversion reactant. The conversion reactant exposure can turn at least a part of the convertible layer (320) into a gap filling fluid that flows into the gap. Optionally, the gap filling fluid can then be solidified to form a solidified material (330). Optionally, the solidified material (330) or gap filling fluid can be converted into a converted material, as described elsewhere herein.

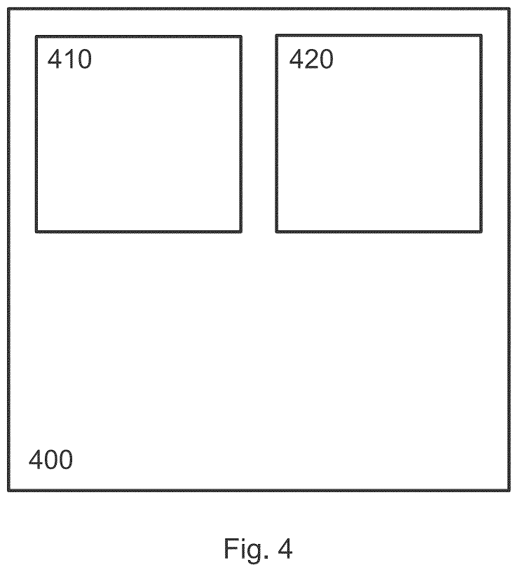

FIG. 4 shows another embodiment of a system (400) as described herein in a stylized way. The system (400) comprises two distinct reaction chambers: a first reaction chamber (410) and a second reaction chamber (420). The first reaction chamber (410) is arranged for forming a convertible layer on a substrate. The second reaction chamber (420) is arranged for at least one of exposing the substrate to conversion reagent and transforming a gap filling fluid into a transformed material. In some embodiments, the substrate moves between the first reaction chamber (410) and second reaction chamber (420) without an air break. In some embodiments, the second reaction chamber (420) is configured to expose the material to the halogen reactant by at least one of the following methods: dip coating, spin coating, sol-gel, or chemical bath.

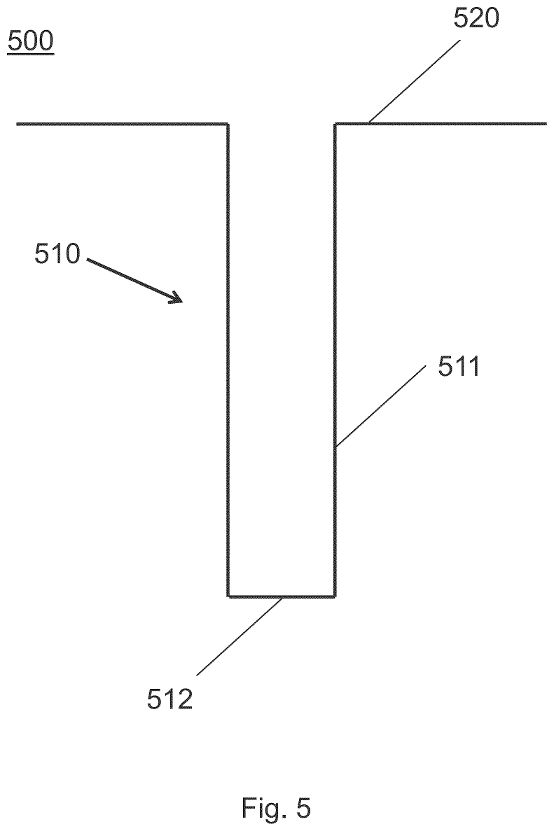

FIG. 5 shows a schematic representation of a substrate (500) comprising a gap (510). The gap (510) comprises a sidewall (511) and a distal end (512). The substrate further comprises a proximal surface (520). In some embodiments, the sidewall (511) and the distal end (512) comprise the same material. In some embodiments, at least one of the sidewall (511) or the distal end (512) comprises a dielectric, such as a silicon containing dielectric such as silicon oxide, silicon nitride, silicon carbide, or mixtures thereof. In some embodiments, at least one of the sidewall (511) and the distal end (512) comprise a metal, such as a transition metal, a post transition metal, or a rare earth metal. In some embodiments, the metal comprises Cu, Co, W, Ru, Mo, Al, or an alloy thereof.

In some embodiments, the sidewall (511) and the distal end (512) have an identical, or a substantially identical, composition. In some embodiments, the sidewall (511) and the distal end (512) have a different composition. In some embodiments, the sidewall and the distal end (512) comprise a dielectric. In some embodiments, the sidewall (511) and the distal end (512) comprise a metal. In some embodiments, the sidewall (611) comprises a metal and the distal end (512) comprises a dielectric. In some embodiments, the sidewall (511) comprises a dielectric and the distal end comprises a metal.

In some embodiments, the proximal surface (520) has the same composition as the sidewall (511). In some embodiments, the proximal surface (520) has a different composition than the sidewall (511). In some embodiments, the proximal surface (520) has a different composition than the distal end (512). In some embodiments, the proximal surface (520) has the same composition as the distal end (512).

In some embodiments, the proximal surface (520), the sidewall (511), and the distal end (512) comprise the same material. In some embodiments, the proximal surface (520), the sidewall (511), and the distal end (512) comprise a dielectric. In some embodiments, the proximal surface (520), the sidewall (511), and the distal end (512) comprise a metal. In some embodiments, the proximal surface (520), the sidewall (511), and the distal end (512) comprise a semiconductor.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for filling a gap, the method comprising:
providing a substrate to a reaction chamber, the substrate comprising the gap;
forming a convertible layer on the substrate; and,
exposing the substrate to a liquid phase conversion reactant, thereby converting at least part of the convertible layer into a gap filling fluid;
wherein the gap filling fluid at least partially fills the gap.

2. The method according to claim 1, wherein the convertible layer comprises at least one of a metal, a metal oxide, a metal nitride, or a metal carbide.

3. The method according to claim 1, wherein the convertible layer comprises a metal atom which is capable of forming a volatile halide or oxyhalide compound.

4. The method according to claim 1, wherein the convertible layer is at least partially metallic or semiconducting.

5. The method according to claim 1, wherein the forming a convertible layer is performed in a first reaction chamber, and the exposing the substrate to a liquid phase conversion reactant is performed in a second reaction chamber.

6. The method according to claim 5, wherein the first and second reaction chambers form part of a cluster tool.

7. The method according to claim 1, wherein the convertible layer comprises an element selected from the group consisting of W, Ge, Sb, Te, Nb, Ta, V, Ti, Zr, Rh, Fe, Cr, Mo, Au, Pt, Ag, Ni, Cu, Co, Zn, Al, In, Sn, and Bi.

8. The method according to claim 1, wherein the liquid phase conversion reactant comprises a halogen.

9. The method according to claim 1, wherein the liquid phase conversion reactant is in the form of an aqueous solution.

10. The method according to claim 1, wherein the liquid phase conversion reactant comprises a hydrogen halide.

11. The method according to claim 1, wherein the liquid phase conversion reactant comprises an oxygen-containing halogen acid.

12. The method according to claim 1, wherein the exposing step is done by at least one of the following methods selected from the group consisting of: dip coating, spin coating, sol-gel, and chemical bath.

13. The method according to claim 1, wherein the liquid phase conversion reactant is heated before and/or during the exposing step.

14. The method according to claim 13, wherein the conversion reactant is heated to a temperature between 20 and 200° C.

15. The method according to claim 1, wherein exposing the substrate to a liquid phase conversion reactant step is performed in an ultrasonic bath.

16. A system comprising,
a reaction chamber;
a precursor gas source comprising a metal precursor;
a deposition reactant gas source comprising a deposition reactant; and
a controller, wherein the controller is configured to control gas flow into the reaction chamber to form a layer on a substrate by a method according to claim 1.

17. A multi-chamber reactor system comprising:
a first reaction chamber configured to deposit a material layer on a substrate; and
a second reaction chamber configured to expose the material layer to a halogen reactant to form a flowable layer.

18. The multi-chamber reactor system of claim 17, wherein the first reaction chamber and second reaction chamber form part of a cluster tool, and wherein the substrate moves between the first reaction chamber and second reaction chamber without an air break.

19. The multi-chamber reactor system of claim 17, wherein the second reaction chamber is configured to expose the material layer to the halogen reactant by at least one of the following methods: dip coating, spin coating, sol-gel, or chemical bath.
